(19) United States
(12) Patent Application Publication
(10) Pub. No.: US 2013/0041604 A1
(43) Pub. Date: Feb. 14, 2013

(54) METHOD OF PREDICTING TRANSIENT STABILITY OF A SYNCHRONOUS GENERATOR AND ASSOCIATED DEVICE

(71) Applicants: Andrzej Wiszniewski, Wroclaw (PL); Waldemar Rebizant, Wroclaw (PL); Andrzej Klimek, Surrey (CA)

(72) Inventors: Andrzej Wiszniewski, Wroclaw (PL); Waldemar Rebizant, Wroclaw (PL); Andrzej Klimek, Surrey (CA)

(73) Assignees: SCHNEIDER ELECTRIC ENERGY UK LTD, Telford (GB); ALSTOM TECHNOLOGY LTD, Baden (CH)

(21) Appl. No.: 13/643,974

(22) PCT Filed: Apr. 28, 2010
(86) PCT No.: PCT/EP2010/055713

§ 371 Date: Oct. 26, 2012

(51) Int. Cl. G06F 19/00; G01R 31/34

(52) U.S. Cl. 702/58

(57) ABSTRACT

A method of predicting transient stability of a synchronous generator and a device for implementing such a method, the device comprising measurement means and calculation means for calculating an information which indicates, before it actually happens, whether the generator slip will be greater than zero or not at the critical phase angle.

### TECHNICAL FIELD AND PRIOR ART

The invention relates to a method of predicting transient stability of a synchronous generator and to a device implementing such a method.

Most of the prior art techniques have a setting for or are setting free to determine the point at which an out-of-step tripping of the generator or the line has to occur. Most of techniques rely on timing the locus of impedance through two load blinders. A problem of the prior art techniques is that they are computationally complex and require a number of settings to operate. In general, it is too late for an intervention which could prevent the instability.

The method of the invention does not have such a drawback.

### SUMMARY OF THE INVENTION

The method of the invention is an efficient method for prediction of generator transient instability after a disturbance has been developed in a power system. Further, the method of the invention allows an analysis of generator's ability to recover a stable state.

Indeed, the invention concerns a method of predicting a transient stability of a synchronous generator which provides an active electric power Pₑ and a reactive power Qₑ to a power system, wherein the method comprises, after a fault has been cleared:
a measurement of the electrical power Pₑ₁, Qₑ₁ at time t₁ and of the electrical power Pₑ₂, Qₑ₂ at time t₂ greater than t₁,
a measurement of the slip of frequency s₁ of the synchronous generator at time t₁ and of the slip of frequency s₂ of the synchronous generator at time t₂,
a calculation, by means of a calculation unit, of:

$$\to Δ P = {P}_{e 2} - {P}_{e 1} ; \\ \to Δ Q = {Q}_{e 2} - {Q}_{e 1} ; \\ \to β = {ω}_{0} ( {t}_{2} - {t}_{1} ) ( {s}_{2} + {s}_{1} ) / 2 ; \\ \to \frac{EV}{Z} = \frac{\sqrt{Δ {P}^{2} + Δ {Q}^{2}}}{2 sin ( \frac{β}{2} )} ; \\ \to {P}_{B} = 0.5 [ ( {P}_{e 2} + {P}_{e 1} ) - ( Δ Q ) ctg ( \frac{β}{2} ) ] ; \\ \to {γ}_{C} = π - {γ}_{p} = π - arcsin [ \frac{Z ( {P}_{m} - {P}_{B} )}{EV} ] ; \\ \to {P}_{A} = {P}_{m} - {P}_{B} ; \\ \to {γ}_{S} = arccos ( \frac{Δ P}{\sqrt{Δ {P}^{2} + Δ {Q}^{2}}} ) ; \\ \to {γ}_{2} = {γ}_{S} + β / 2 ; \\ \to QT = \frac{1}{{ω}_{0} {HP}_{r}} [ \frac{EV}{Z} ( cos {γ}_{2} - cos {γ}_{C} ) - {P}_{A} ( {γ}_{C} - {γ}_{2} ) ] ;$$

With ω₀, H, Pᵣ and Pₘ being predetermined parameters:
ω₀ being a nominal angular frequency of the synchronous generator;
H being an inertia constant of the rotating masses of the synchronous generator;
Pᵣ being a reference power at which the inertia constant H has been determined;
Pₘ being a mechnanical power which drives the synchronous generator, and
a comparison of QT with s₂² so that:

If s₂²≦QT, the generator maintains stable operation after the initiating fault has been cleared.

If QT<s₂², transient instability is predicted.

The invention also relates to a device implementing the method of the invention.

The method of the invention enables advantageously close control of evolving dynamic instability, thus helping retain the generator in service in very controllable manner and offer the system operator the information that can be used in rearranging re-configuration of system topology in a timely manner thus contributing to avoiding loss of the generation potentially leading to blackouts.

### BRIEF DESCRIPTION OF THE DRAWINGS

Other characteristics and advantages of the invention will become clearer upon reading a preferred embodiment of the invention made in reference to the attached figures, wherein:

FIG. 1 represents an equivalent circuit of the electrical circuit implementing the method of the invention; and

FIG. 2 is a curve allowing to explain the method of the invention.

### DETAILED DESCRIPTION OF THE PREFERRED EMBODIMENT OF THE INVENTION

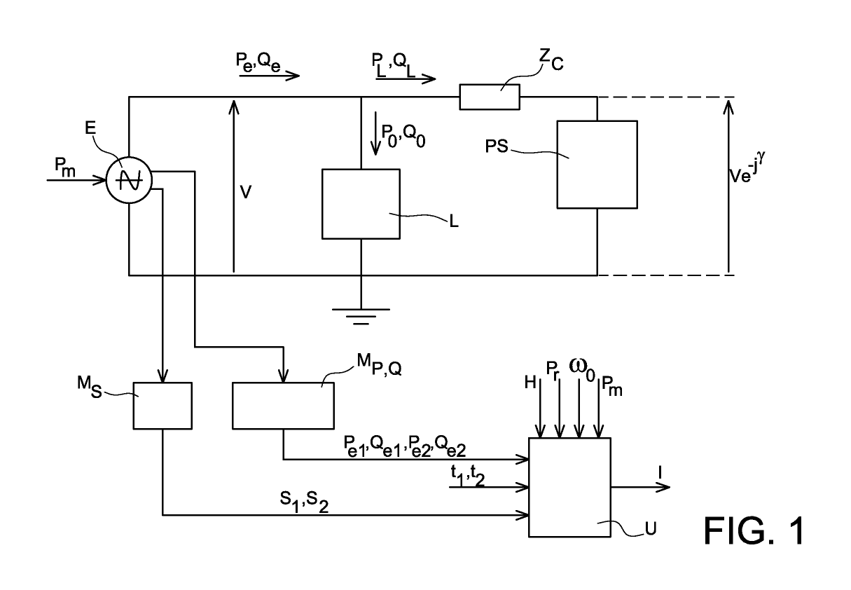

FIG. 1 represents an equivalent circuit of the electrical circuit which implements the method of the invention.

The equivalent circuit comprises a synchronous generator E, a load L, a connection impedance Z_{C}, a power system PS, two measurement devices M_{P,Q} and M_{S} and a calculator U. The load L is connected at the generator terminals and the connection impedance Z_{C} connects the generator E to the power system PS. A mechanical power Pₘ drives the generator E and an electrical power Pₑ, Qₑ (Pₑ is the active power and Qₑ is the reactive power) is provided at the generator terminals. The electrical power Pₑ, Qₑ is divided between the electrical power Pₒ, Qₒ provided to the load L (Pₒ is the active power and Qₒ is the reactive power) and the electrical power P_{L}, Q_{L} provided to the set constituted by the connection impedance Z_{C} and the power system PS (P_{L} is the active power and Q_{L} is the reactive power).

There is a voltage V at the terminals of the generator E and there is a voltage Ve^{-jγ} at the terminals of the power system PS. The connection impedance Z_{C} is such that:

Z_{C}=Ze^{jφ}

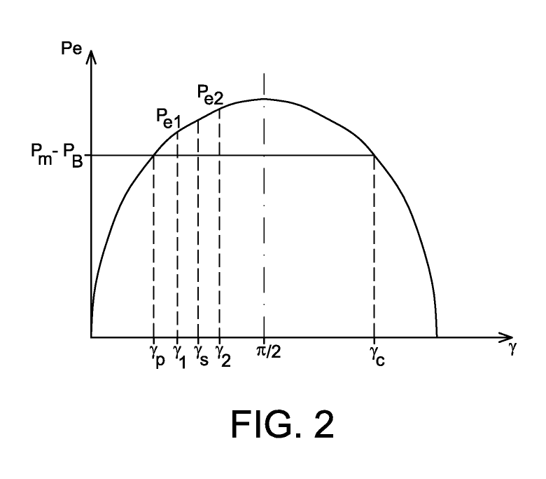

During the normal operation, the mechanical power Pₘ is matched by the electrical power Pₑ at a particular phase angle γ_{P} of the phase angle γ (see FIG. 2). The phase angle γ_{P} is:

γ_{P}=arcsin (Z×(Pₘ−P_{B})/E×V),

where P_{B} is the power derived from the generator by the local load L (P₀) plus power losses in the connecting impedance Z_{C}. As it is known by the man skilled in the art, there is a critical angle γ_{C} which corresponds to angle γ_{P}:

γ_{C}=π−γ_{P}

(cf. FIG. 2)

The slip of frequency s of the synchronous generator is given by the formula:

s=(ω−ωₒ)/ωₒ,

ω being the current angular frequency of the generator E and ωₒ being the nominal angular frequency of the synchronous generator E.

At the angle γ_{P}, the slip may be greater than zero and, because of that, the generator angle increases. For angles γ greater than γ_{P} and smaller than γ_{C}, the electrical power Pₑ is greater than the mechanical power Pₘ, therefore the generator decelerates, and in consequence the slip decreases. The transient angular stability becomes lost if, at the critical angle γ_{C}, the slip is still greater than zero. If it would be so, the mechanical power would be greater than the electrical power and the generator would accelerate, leading to pole slip. The accelerating power P_{A} is:

P_{A}=Pₘ−P_{B}

For an angle γ_{M} measured between γ_{P} and γ_{C}, the condition of stability is respected if the slip s_{M} associated with the angle γ_{M} is:

$${s}_{M}^{2} \leq \frac{1}{{ω}_{0} {HP}_{r}} [ \frac{EV}{Z} ( cos {γ}_{M} - cos {γ}_{C} ) - {P}_{A} ( {γ}_{C} - {γ}_{M} ) ] \qquad ( 1 )$$

Where H is the inertia constant of the rotating masses of the system (generator+prime mover) and Pᵣ is a reference power at which the inertia constant H has been determined (Pᵣ is generally the rated power of the generator).

The device of the invention comprises means to check if the inequality (1) is respected or not. To do so, the device of the invention comprises measurement devices M_{P,Q} and M_{S}and a calculator U.

Therefore, after a fault has been cleared, the measurement device M_{P,Q} measures the electrical power Pₑ₁, Qₑ₁ at time t₁ and the electrical power Pₑ₂, Qₑ₂at time t₂ (t₂>t₁) and the measurement device M_{S} measures the corresponding slips s₁ and s₂ at respective times t₁ and t₂ (cf. FIG. 2). At time t1, the angle γ is γ₁ and, at time t₂, the angle γ is γ₂. Measurement data t₁, Pₑ₁, Qₑ₁, s₁, and t₂, Pₑ₂, Qₑ₂, s₂ are input data of the calculation unit U.

First, the calculation unit U calculates:

ΔP=Pₑ₂−Pₑ₁,

ΔQ=Qₑ₂−Qₑ₁, and

β=γ₂−γ₁ , by means of s₂, t₂, s₁ and t₁.

Indeed:

$$β = {ω}_{0} {\int }_{{t}_{1}}^{{t}_{2}} s d t ,$$

and therefore

β#ω₀×(t₂−t₁)×(s₂+s₁)/2

Then, the angle γ_{S} (γ_{S}=[γ₂+γ₁]/2) and γ₂ are calculated:

$${γ}_{S} = arccos ( \frac{Δ P}{\sqrt{Δ {P}^{2} + Δ {Q}^{2}}} ) , \\ {γ}_{2} = {γ}_{S} + β / 2$$

Also, the quantity EV/Z and the power P_{B} are calculated:

$$\frac{EV}{Z} = \frac{\sqrt{Δ {P}^{2} + Δ {Q}^{2}}}{2 sin ( \frac{β}{2} )} , and$$

$${P}_{B} = 0.5 [ ( {P}_{e 2} + {P}_{e 1} ) - ( Δ Q ) ctg ( \frac{β}{2} ) ]$$

As already mentioned, the angle γC which corresponds to the unstable equilibrium and the acceleration power P_{A} are respectively:

$${γ}_{C} = π - {γ}_{p} = π - arcsin [ \frac{Z ( {P}_{m} - {P}_{B} )}{EV} ] ,$$

and

P_{A}=Pₘ−P_{B}

So, the angle γ_{C} and the acceleration power P_{A} are also calculated.

Then, the calculation unit calculates the quantity QT such that:

$$QT = \frac{1}{{ω}_{0} {HP}_{r}} [ \frac{EV}{Z} ( cos {γ}_{2} - cos {γ}_{C} ) - {P}_{A} ( {γ}_{C} - {γ}_{2} ) ]$$

QT is then compared with s₂².

If s₂²≦QT, the generator maintains stable operation after the initiating fault has been cleared.

If QT<s₂², transient instability can be predicted.

So, the process of the invention allows advantageously to get an information I which indicates, before it actually happens, whether the slip will be greater than zero or not at the critical phase angle.

The prediction method of the invention calculates the information I based on measurements of locally available signals: active and reactive powers, their rate of change, and rotor slip. Knowing those parameters, the critical phase angle can be determined and it is possible to check before it actually happens whether the slip will be greater than zero at the critical angle. The measurement device M_{P,Q} is for example a computer or a microprocessor with implemented appropriate algorithms for active and reactive power measurement. The measurement device M_{S} is for example analogue or digital generator rotating speed and slip measurement unit. The calculator U is, for example, a computer or a microprocessor.

1. Method of predicting a transient stability of a synchronous generator (E) which provides an active electric power Pₑ and a reactive power Qₑ to a power system (PS), wherein the method comprises, after a fault has been cleared:
a measurement of the electrical power Pₑ₁, Qₑ₁ at time t₁ and of the electrical power Pₑ₂, Qₑ₂ at time t₂ greater than t₁,
a measurement of the slip of frequency s₁ of the synchronous generator at time t₁ and of the slip of frequency s₂ of the synchronous generator at time t₂,
a calculation, by means of a calculation unit (U), of:
$$\to Δ P = {P}_{e 2} - {P}_{e 1} ; \\ \to Δ Q = {Q}_{e 2} - {Q}_{e 1} ; \\ \to β = {ω}_{0} ( {t}_{2} - {t}_{1} ) ( {s}_{2} + {s}_{1} ) / 2 ; \\ \to \frac{EV}{Z} = \frac{\sqrt{Δ {P}^{2} + Δ {Q}^{2}}}{2 sin ( \frac{β}{2} )} ; \\ \to {P}_{B} = 0.5 [ ( {P}_{e 2} + {P}_{e 1} ) - ( Δ Q ) ctg ( \frac{β}{2} ) ] ; \\ \to {γ}_{C} = π - {γ}_{p} = π - arcsin [ \frac{Z ( {P}_{m} - {P}_{B} )}{EV} ] ; \\ \to {P}_{A} = {P}_{m} - {P}_{B} ; \\ \to {γ}_{S} = arccos ( \frac{Δ P}{\sqrt{Δ {P}^{2} + Δ {Q}^{2}}} ) ; \\ \to {γ}_{2} = {γ}_{S} + β / 2 ; \\ \to QT = \frac{1}{{ω}_{0} {HP}_{r}} [ \frac{EV}{Z} ( cos {γ}_{2} - cos {γ}_{C} ) - {P}_{A} ( {γ}_{C} - {γ}_{2} ) ] ;$$
With ω₀, H, Pᵣ and Pₘ being predetermined parameters:
ω₀ being a nominal angular frequency of the synchronous generator (E);
H being an inertia constant of the rotating masses of the synchronous generator;
Pᵣ being a reference power at which the inertia constant H has been determined;
Pₘ being a mechnanical power which drives the synchronous generator, and
a comparison of QT with s₂² so that:
If s₂²≦QT, the generator maintains stable operation after the initiating fault has been cleared.
If QT<s₂², transient instability is predicted.

2. Device for predicting a transient stability of a synchronous generator (E) which provides an active electric power Pₑ and a reactive power Qₑ to a power system (PS), wherein the device comprises :
a measurement device (M_{P,Q}) which measures the electrical power Pₑ₁, Qₑ₁ at time t₁ after a fault has been cleared and the electrical power Pₑₑ, Qₑ₂ at time t₂ greater than t₁,
a measurement device (Mₛ) which measures the slip of frequency s₁ of the synchronous generator at time t₁ and of the slip of frequency s₂ of the synchronous generator at time t₂,
a calculation unit (U) which calculates:
$$\to Δ P = {P}_{e 2} - {P}_{e 1} ; \\ \to Δ Q = {Q}_{e 2} - {Q}_{e 1} ; \\ \to β = {ω}_{0} ( {t}_{2} - {t}_{1} ) ( {s}_{2} + {s}_{1} ) / 2 ; \\ \to \frac{EV}{Z} = \frac{\sqrt{Δ {P}^{2} + Δ {Q}^{2}}}{2 sin ( \frac{β}{2} )} ; \\ \to {P}_{B} = 0.5 [ ( {P}_{e 2} + {P}_{e 1} ) - ( Δ Q ) ctg ( \frac{β}{2} ) ] ; \\ \to {γ}_{C} = π - {γ}_{p} = π - arcsin [ \frac{Z ( {P}_{m} - {P}_{B} )}{EV} ] ; \\ \to {P}_{A} = {P}_{m} - {P}_{B} ; \\ \to {γ}_{S} = arccos ( \frac{Δ P}{\sqrt{Δ {P}^{2} + Δ {Q}^{2}}} ) ; \\ \to {γ}_{2} = {γ}_{S} + β / 2 ; \\ \to QT = \frac{1}{{ω}_{0} {HP}_{r}} [ \frac{EV}{Z} ( cos {γ}_{2} - cos {γ}_{C} ) - {P}_{A} ( {γ}_{C} - {γ}_{2} ) ] ;$$
With ω₀, H, Pᵣ and Pₘ being predetermined parameters:
ω₀ being a nominal angular frequency of the synchronous generator (E);
H being an inertia constant of the rotating masses of the synchronous generator;
Pᵣ being a reference power at which the inertia constant H has been determined;
Pₘ being a mechnanical power which drives the synchronous generator, and
comparison means (U) to compare QT with s₂² so that:
If s₂²≦QT, the generator maintains stable operation after the initiating fault has been cleared.
If QT<s₂², transient instability is predicted.
